(19) United States
(12) Patent Application Publication
(10) Pub. No.: US 2014/0216658 A1
(43) Pub. Date: Aug. 7, 2014

(54) VACUUM PROCESSING DEVICE

(71) Applicant: HITACHI HIGH-TECHNOLOGIES CORPORATION, Tokyo (JP)

(72) Inventors: Shigeharu Minami, Yamaguchi (JP); Satomi Inoue, Yamaguchi (JP)

(21) Appl. No.: 14/239,192

(22) PCT Filed: Aug. 2, 2012
(86) PCT No.: PCT/JP2012/069741

§ 371 Date: Mar. 17, 2014

(30) Foreign Application Priority Data
Jan. 10, 2012 (JP) 2012-001768

(51) Int. Cl. H01L 21/677

(52) U.S. Cl. CPC H01L 21/67739; H01L 2221/68304
USPC 156/345.31

(57) ABSTRACT

To provide a vacuum processing device (100) capable of reducing a decline in processing throughput, said vacuum processing device (100) is provided with multiple vacuum transport chambers (41) (42) and a lock chamber (31), and transports and performs processing on a wafer to be processed. Said vacuum transport chambers (41) (42): are placed behind an atmosphere transport chamber (21); transport the wafer to be processed therein; and have connected to the perimeter thereof, vacuum processing chambers (61) (62) (63) that use a plasma to process the wafer to be processed. Said lock chamber (31) is placed between an intermediate chamber (32) and the rear surface of the atmosphere transport chamber (21). While being transported between said vacuum transport chambers (41) (42), the wafer to be processed is placed in and stored by said intermediate chamber (32). To one of the multiple vacuum processing chambers (61) (62) (63), by way of the lock chamber (31), said vacuum processing device (100) transports said wafer to be processed, which is stored in a cassette placed on a cassette stand, and processes said wafer to be processed. In the vacuum processing device (100), a dummy wafer storage section is placed within the intermediate chamber (32). Said dummy wafer storage section is placed within a processing chamber (61) (62) (63) when the plasma is formed in the processing chamber (61) (62) (63) and processing is done by the processing chamber (61) (62) (63) using a dummy wafer and a different condition from the first-mentioned processing.

### TECHNICAL FIELD

The present invention relates to a vacuum processing apparatus which is adapted to process a processing object substrate such as a semiconductor wafer in a processing chamber disposed in a vacuum vessel and which includes a transfer vessel coupled to the vacuum vessel and allowing the processing object substrate to be transferred therethrough.

### BACKGROUND ART

In the above-described apparatus, or particularly a vacuum processing apparatus where a substrate-like sample such as a semiconductor wafer, namely a processing object sample (hereinafter, referred to as “wafer”) is processed in a processing chamber that is disposed in the vacuum vessel and decompressed, product particles produced in the processing chamber during processing are adhered to and deposited on inside walls of the processing chamber and surfaces of members disposed in the processing chamber as the number of wafers processed in the processing chamber increases. The increase in amount of such adherent substances may lead to a problem that interaction between the surface of the adherent substances and plasma generated in the processing chamber during the wafer processing or force derived from opening or closing a valve for hermetically dividing the interior of processing chamber from outside liberates the adherent substances again from the surface to which the substances adhere, and the liberated substances are suspended in the processing chamber and adhere to the wafer, forming foreign matter thereon.

It is therefore a general practice to remove the adherent substances from the inner surface of the above-described processing chamber after processing a predetermined number of wafers or after a lapse of a predetermined period of time. Such a cleaning of the interior of processing chamber includes: plasma cleaning in which the semiconductor wafer for device production to be processed into an element for semiconductor device is not placed in the processing chamber while plasma generated in the processing chamber is used to remove the adherent substances byway of interaction between the plasma and the product particles; and wet cleaning in which the interior of the vacuum vessel is brought back to the atmospheric pressure and the processing chamber is opened to the atmosphere before a worker washes or cleans the surfaces of the members in the processing chamber.

Since the work such as the wet cleaning takes longer time, it is a common practice that the plasma cleaning is performed at intervals of predetermined number of processed wafers or of predetermined total process time and the above-described wet cleaning is performed after repetition of a predetermined number of plasma cleanings. Depending upon the type of film on the surface of wafer as a processing object or upon processing conditions, the plasma cleaning is also performed each time one wafer is processed.

Further, plural wafers having a film layer formed from the same material and in the same structure are regarded as belonging to one group (lot). Before processing any lot, plasma is generated in the processing chamber with no wafers for device production placed therein so as to bring the inner surfaces of the processing chamber close to a state during the plasma processing of the wafers for device production, which processing is to be performed subsequently. Thus, the subsequent plasma processing of wafer is stabilized. Namely, a seasoning process for seasoning the wall surfaces to plasma is commonly performed. For this seasoning process, gas and electric field supplies and pressure are adjusted to provide the same conditions as in the processing of the wafers for device production.

When such a cleaning (plasma cleaning) or seasoning is performed, a so-called dummy substrate (hereinafter, referred to as “dummy wafer”) is commonly used in order to prevent that the plasma generated in the processing chamber is adsorbed on the wafer placed in the processing chamber while a sample mounting surface of a sample stage on which the wafer is retained is worn or deteriorated by interaction with the plasma. The dummy wafer is different from the wafer for device production and is for use in cleaning or seasoning.

In such a vacuum processing apparatus, a plurality of wafers stored in a cassette transferred under atmospheric pressure and placed on a stage disposed at the front of the apparatus are taken out one by one and transferred to a predetermined processing chamber in a vacuum vessel one by one. The wafer transfer is commonly performed by at least one transfer robot. The wafers are exchanged in the cassette with a wafer carry-in port of a switching mechanism (hereinafter, referred to as “load port”) of the apparatus opened, which mechanism has the wafer carry-in port on the front side of the vacuum processing apparatus and faces a cassette stand and a wafer outlet port of the cassette placed on the cassette stand.

A transferred wafer is processed in a processing chamber and thereafter, is transferred in the opposite direction of the wafer delivery into this processing chamber so as to be returned to an original storage position in the original cassette. In a case where an unprocessed wafer exists in the cassette, this wafer is taken out, transferred and processed the same way as the previously processed processing object wafer.

On the other hand, in a case where the cleaning or seasoning is performed using the dummy wafer, as described above, a cassette storing at least one dummy wafer therein is placed on the cassette stand disposed at the front of the vacuum processing apparatus the same way as the cassette storing the processing object wafer. The dummy wafer is transferred to the processing chamber by the transfer robot. After completion of the cleaning process or seasoning process, the dummy wafer is returned to its original position in the dummy wafer cassette. Japanese Patent Application Laid-Open No. 2008-27937 (Patent Literature 1), Japanese Patent Application Laid-Open No. 2001-250780 (Patent Literature 2), and Japanese Patent Application Laid-Open No. 2004-153185 (Patent Literature 3) are known to represent such examples of the prior art.

Disclosed in Patent Literature 1 is an apparatus where the dummy wafer in the cassette placed on the cassette stand is transferred to a dummy wafer storage space provided in an atmospheric transfer chamber disposed on the front side of the apparatus and thereafter, the dummy wafer is taken out from the storage space and transferred to a vacuum-side processing chamber. Further, Patent Literature 2 discloses an apparatus where the dummy wafer is stored in a cassette having the same shape and structure as a cassette for the processing object wafer and this cassette is placed on the cassette stand; the above cassette storing the processing object wafer is placed in a lock chamber disposed between the atmospheric transfer chamber and the vacuum transfer chamber and serving to deliver the wafer therebetween; a shelf to store the dummy wafer is disposed in the lock chamber under the cassette storing the processing object wafer; and the dummy wafer stored in the shelf at the lower area in the lock chamber is taken out and used when the dummy wafer is used for cleaning of the processing chamber or the like.

### CITATION LIST

### Patent Literatures

Patent Literature 1: Japanese Patent Application Laid-Open No. 2008-027937
Patent Literature 2: Japanese Patent Application Laid-Open No. 2001-250780
Patent Literature 3: Japanese Patent Application Laid-Open No. 2004-153185

### SUMMARY OF INVENTION

### Technical Problem

The above-described prior arts have paid inadequate consideration to the following points. Ina case where the cleaning or seasoning using the dummy wafer is performed in the vacuum processing apparatus before or after the processing of the processing object wafer, the transfer of the dummy wafer to the processing chamber of interest need be performed in parallel with the transfer of the processing object wafer if the dummy wafer is to be supplied from the wafer storage space adjoining the load port or the atmospheric transfer chamber. Namely, the dummy wafer to be transferred is interposed in the queue of processing object wafers for device production to be transferred, resulting in the decrease in transfer efficiency of processing object wafers, or the decrease in the number of processing object wafers transferred per unit time. The vacuum processing apparatus declines in processing-object wafer throughput.

In the case where the additional storage space is provided, specialized mechanism, space and the like for the use of dummy wafer but not for the purpose of processing the processing object wafer are required, which constitutes a causative factor for increase in apparatus costs.

In the vacuum processing apparatus where the cleaning or seasoning using the dummy wafer is performed before or after the processing object wafer is processed, an object of the invention is to provide a vacuum processing apparatus capable of preventing the decline in throughput.

### Solution to Problem

The above object is accomplished in a vacuum processing apparatus wherein a plurality of vacuum transfer chambers each of which has at least one vacuum processing chamber coupled thereto are arranged rearward of an atmospheric transfer chamber and coupled together with an intermediate chamber interposed therebetween, and a processing using a dummy wafer is performed in the vacuum processing chamber before or after a processing is performed in the vacuum processing chamber, the vacuum processing apparatus which is provided with a space for storing the dummy wafer in the intermediate chamber.

Further, the dummy wafer may be stored in a processed-wafer storage section disposed in the storage space in the intermediate chamber. Otherwise, the intermediate chamber may include therein storage spaces to store both unprocessed wafer and processed wafer and a dummy wafer storage space may be disposed under the storage space for the processed wafer.

### Advantageous Effects of Invention

According to the invention, the vacuum processing apparatus capable of reducing the decline in throughput can be provided.

### BRIEF DESCRIPTION OF DRAWINGS

FIG. 1 is a top view schematically illustrating a general structure of a vacuum processing apparatus according to an embodiment of the invention;

FIG. 2 is a top view showing a structure of a vacuum transfer chamber according to the embodiment shown in FIG. 1;

FIG. 3 is a cross-sectional view showing in enlarged dimension a vacuum transfer intermediate chamber according to the embodiment shown in FIG. 1; and

FIG. 4 is a top view schematically illustrating a general structure of a vacuum processing apparatus according to a modified example of the invention.

### DESCRIPTION OF EMBODIMENTS

A vacuum processing apparatus according to an embodiment of the invention will hereinbelow be described in detail with reference to the accompanying drawings. It should be understood that the following embodiments are given to illustrate specific examples of the invention and the invention is not limited to these embodiments. Rather, the invention can be modified by those skilled in the art to incorporate any number of variations and alterations within the scope of technical ideas disclosed herein.

Throughout the figures illustrating the embodiments, similar reference numerals are assigned to equal or similar components which are explained only once in most cases to avoid repetition.

### Embodiment

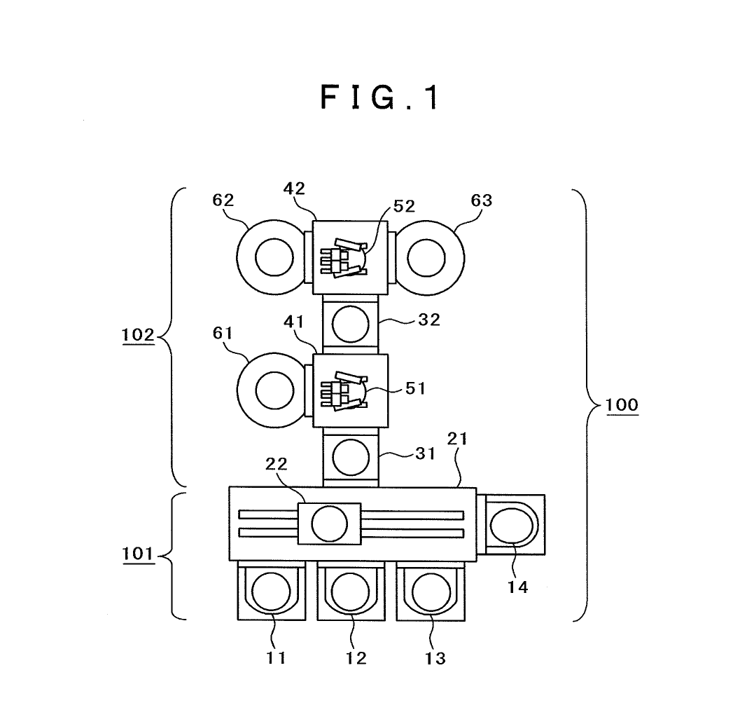

The embodiment of the invention is described as below with reference to FIG. 1 to FIG. 3. FIG. 1 is a top view schematically illustrating a general structure of a vacuum processing apparatus according to the embodiment of the invention.

A vacuum processing apparatus 100 according to the embodiment of the invention shown in FIG. 1 and including a vacuum processing chamber is roughly divided into an atmosphere-side block 101 and a vacuum-side block 102. The atmosphere-side block 101 includes a part for transferring a substrate-like sample such as a semiconductor wafer as a processing object (hereinafter, referred to as “wafer”) to a vacuum-side processing part under atmospheric pressure, and load ports 11, 12, 13 on which cassettes storing wafers therein are placed. The vacuum-side block 102 is a block where the wafer is transferred under pressure decompressed from the atmospheric pressure and processed in a predetermined vacuum processing chamber. Between a site in the vacuum-side block 102 where the above-described transfer and processing are performed and the atmosphere-side block 101, there is disposed a section which interconnects these portions and in which the sample is held while the pressure is varied between the atmospheric pressure and vacuum.

The atmosphere-side block 101 includes a housing 21 which has a substantially rectangular shape and is equipped with an atmospheric transfer robot 22 that is disposed in a transfer chamber defining an internal transfer space under the atmospheric pressure or pressure substantially considered to be equivalent to the atmospheric pressure, and that transfers the wafer through the space as holding the wafer on its hand. The cassette storing a processing object wafer or a dummy wafer for cleaning or seasoning can be placed on the above-described load ports 11, 12, 13 attached to a front side of this housing 21. Aside from the load ports 11, 12, 13, as shown in the figure, the atmosphere-side block further includes a dummy wafer store portion 14 attached to a side wall at an right end (the right side as seen from the front of the vacuum processing apparatus 100) of the housing 21 as seen in the figure. This store portion 14 is internally provided with a rack or shelf part which stores as many wafers as to form one lot in a vertically spaced stacked relation, just as in the cassette.

The vacuum-side block 102 includes a lock chamber 31 which is disposed between a first vacuum transfer chamber 41 and the atmosphere-side block 101 and which varies the internal pressure between the atmospheric pressure and vacuum as containing therein the wafer to be transferred. Although only one lock chamber 31 is shown in FIG. 1 as seen from above, the embodiment includes a plurality (two in the example shown in FIG. 1) of lock chambers of the same dimensions or substantially considered to be of equal dimensions which are arranged in vertically stacked relation. It is noted that a plurality of lock chambers 31 are hereinafter merely described as the lock chamber 31 unless particularly stated otherwise.

The lock chamber 31 according to the embodiment includes two gate valves for opening or hermetically closing openings disposed at front and rear ends thereof. When the internal pressure of the lock chamber 31 is determined to be substantially equal to that of the first vacuum transfer chamber 41 or that of the atmosphere-side housing 21 defined by either one of these front and rear gate valves, the corresponding gate valve is opened to allow the interior of the lock chamber 31 to be communicated with the first vacuum transfer chamber 41 or the atmosphere-side housing 21 so as to allow the transfer robot to transfer the wafer through the gate as will be described hereinlater.

The vacuum-side block 102 is apart for wafer processing where plurality vacuum vessels having the respective interiors decompressed to a predetermined degree of vacuum are coupled together, and the wafer is transferred through the coupled vacuum vessels. The embodiment has a structure where one or more processing unit 1 including a processing vacuum vessel having a processing chamber into which the wafer is transferred and in which plasma is generated is coupled to a vacuum transfer unit including a plurality of transfer vacuum vessels coupled together.

The vacuum-side block 102 includes, as the vacuum transfer unit, the lock chamber 31, the first vacuum transfer chamber 41 coupled to this lock chamber, and a second vacuum transfer chamber 42 disposed on a rear side in a fore-aft direction (in the vertical direction as seen in the figure) of this vacuum processing apparatus 100 and coupled to this first vacuum transfer chamber. Each of the first vacuum transfer chamber 41 and second vacuum transfer chamber 42 is a unit including a vacuum vessel having a flat configuration or a substantially rectangular configuration. These vacuum transfer chambers are two units having so little difference in structure that they can be considered as substantially the same.

A vacuum transfer intermediate chamber 32 is disposed between opposite side walls of vacuum vessels constituting the first vacuum transfer chamber 41 and the second vacuum transfer chamber 42, interconnecting these vacuum transfer chambers which are arranged in the fore-aft direction. The vacuum transfer intermediate chamber 32 is a vacuum vessel the interior of which can be decompressed to an equivalent vacuum degree to that of other vacuum transfer chambers or vacuum processing chambers and which has a configuration that can be regarded as a rectangular parallelepiped. The vacuum transfer intermediate chamber 32 interconnects the first vacuum transfer chamber 41 and the second vacuum transfer chamber 42, having an internal chamber communicated with these vacuum transfer chambers.

Further, a storage section for horizontally retaining a plurality of wafers with spacing defined between the respective upper sides and lower sides of these wafers is disposed in a chamber in the vacuum transfer intermediate chamber 32. The storage section is a shelf which supports the wafers on the lower sides thereof as storing the wafers therein. The storage section has a function of a relay chamber which temporarily stores the wafer when the wafer carried on the shelf with transverse marginal spacing provided at the ends of the wafer diameter is transferred between the first vacuum transfer chamber 41 and the second vacuum transfer chamber 42. Namely, the wafer is carried out and placed in the storage section by a vacuum transfer robot in one of the vacuum transfer chambers and then, is carried out by a robot in the other vacuum transfer chamber and transferred to the vacuum processing chamber or the lock chamber coupled to the vacuum transfer chamber of interest.

The first vacuum transfer chamber 41 is connected with one vacuum processing chamber 61. The second vacuum transfer chamber 42 is configured to be coupled with three vacuum processing chambers. According to the embodiment, however, the second vacuum transfer chamber is coupled with up to two vacuum processing chambers 62, 63. The first vacuum transfer chamber 41 and the second vacuum transfer chamber 42 each define a transfer chamber internally. An unprocessed wafer or processed wafer is transferred through the decompressed internal transfer chamber by a vacuum transfer robot 51 or 52 (described hereinlater) so as to be transferred between the vacuum processing chamber 61 or 62, 63 and the lock chamber 31 or the vacuum transfer intermediate chamber 32.

According to the embodiment, the first vacuum transfer chamber 41 and the second vacuum transfer chamber 42 are vacuum vessels which practically have the same structure, dimensions, configuration and arrangement, and the four side walls (to be considered as four surfaces) of which are provided with passages having the same configuration and allowing the wafer to be transferred therethrough and gates defining an opening of the passage and similarly having the same structure. According to the embodiment, the vacuum vessel and the vessel constituting the vacuum transfer chamber are connected and coupled to each other via gates of the same specifications.

In the first vacuum transfer chamber 41, the vacuum transfer robot 51 for transferring the wafer under vacuum between the lock chamber 31 and either of the vacuum processing chamber 61 and the vacuum transfer intermediate chamber 32 is disposed centrally of the internal space thereof. In the second vacuum transfer chamber 42 as well, the vacuum transfer robot 52 is similarly disposed centrally of the internal space thereof, transferring the wafer between the vacuum transfer intermediate chamber and the vacuum processing chamber 62 or the vacuum processing chamber 63.

FIG. 1 shows only the vacuum processing chamber 61 as the vacuum processing chamber is coupled to the first vacuum transfer chamber 41. The vacuum transfer robot 51 in the vacuum transfer chamber 41 transfers a processing object wafer between the lock chamber 31 and the vacuum processing chamber 61 coupled to the first vacuum transfer chamber 41, and also transfers the processing object wafer between the vacuum transfer intermediate chamber 32 and the lock chamber 31 when the processing object wafer is returned to the atmosphere-side block 101 after the wafer transferred by the second vacuum transfer robot 52 is processed in the two vacuum processing chambers 62, 63. Even though another vacuum processing chamber is coupled to the first vacuum transfer chamber 41 in order to reduce motion load on the vacuum transfer robot 51 and the vacuum transfer robot 52, and deviation of motion time thereof, the transfer of the wafer to this vacuum processing chamber may be inhibited to disable the operation of this vacuum processing chamber.

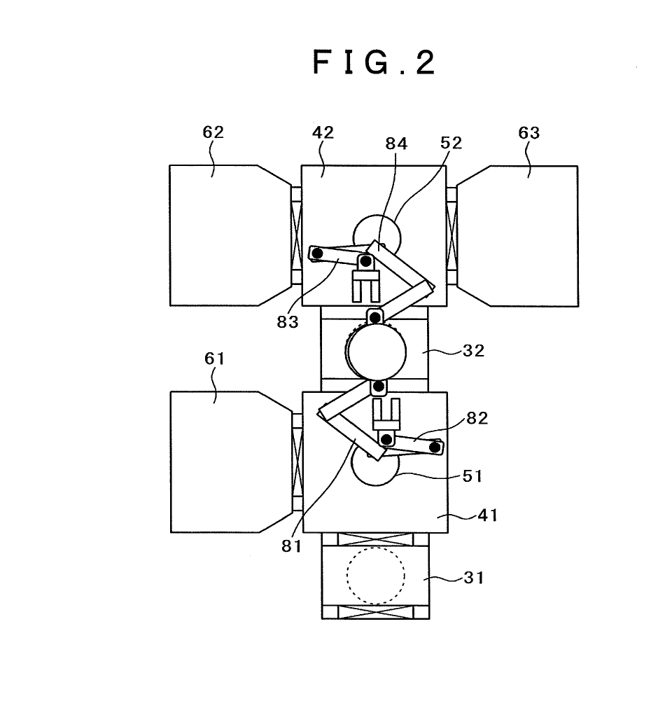

FIG. 2 is a schematic diagram as seen from above, which shows in enlarged dimension the portions including the lock chamber 31, the first and second vacuum transfer chambers 41, 42 and the vacuum processing chambers 61, 62, 63 coupled to these chambers as shown in FIG. 1 and described. Referring to this figure, the vacuum processing chambers 61, 62, 63 are internally provided with processing chambers of the same structure and are adapted to process the wafer by using the plasma generated in the processing chambers. The detailed illustration of the structure is dispensed with. On the other hand, the figure schematically shows the outside configuration of the first and second vacuum transfer chambers 41, 42 and the structure of the vacuum transfer robots 51, 52 disposed therein.

The vacuum transfer robot 51 is disposed centrally of a transfer space in the first vacuum transfer chamber 41 and has plural arms each of which is formed of a plurality of beam-like arm members coupled together by means of a plurality of joint parts disposed at respective ends thereof and is capable of rotational movement about axes of these joint parts.

The robot also has hand parts at respective distal ends of the arms, which are capable of carrying wafers thereon.

According to the embodiment, the vacuum transfer robot 51 includes two arms of first arm 81 and second arm 82. The most proximal one of the plural arm parts of each arm has an end articulated to a rotary cylinder disposed centrally of the first vacuum transfer chamber 41 and rotatable about a vertical axis (in direction perpendicular to the drawing surface). The joint part articulated to the rotary cylinder is configured to be capable of rotational movement about the above-described vertical axis and shifting the position of an end of the arm member coupled to the joint part in the direction of the vertical axis. The vacuum transfer robot 51 is configured to extend and contract or raise and lower the individual arms by drivably rotating the individual arm members through desired angles about the respective joint parts thereof in a manner to change the length from the joint coupled to the rotary cylinder on the central axis to the position equivalent to the center of wafer on the hand at the distal end of the arm and the height from the rotary cylinder to the arm root or the position equivalent to the center of wafer on the hand.

The vacuum transfer robot 52 is disposed centrally of a transfer space in the second vacuum transfer chamber 42 and has the same structure as the vacuum transfer robot 51. Namely, the robot includes a first arm 83 and a second arm 84 each having a plurality of arms and a plurality of joint parts coupling these arms and is capable of increasing or decreasing the distance between the hand carrying the wafer thereon and the rotational axis of the root part of the vacuum transfer robot 52 by extending or contracting these arms. While the above-described transfer robots of the embodiment are configured to include two arms, the robot may include more than two arms.

Further, the rotary cylinder coupled to the root part of each arm is configured to be driven into rotation about the center axis thereof so as to change angular position between the center axis and the root part of the arm around the axis. This permits the respective arms to be rotatably moved to positions opposite the gates communicating the vacuum processing chambers 61 to 63 with the first vacuum transfer chamber 41 and the second vacuum transfer chamber 42 coupled to the vacuum processing chambers 61 to 63.

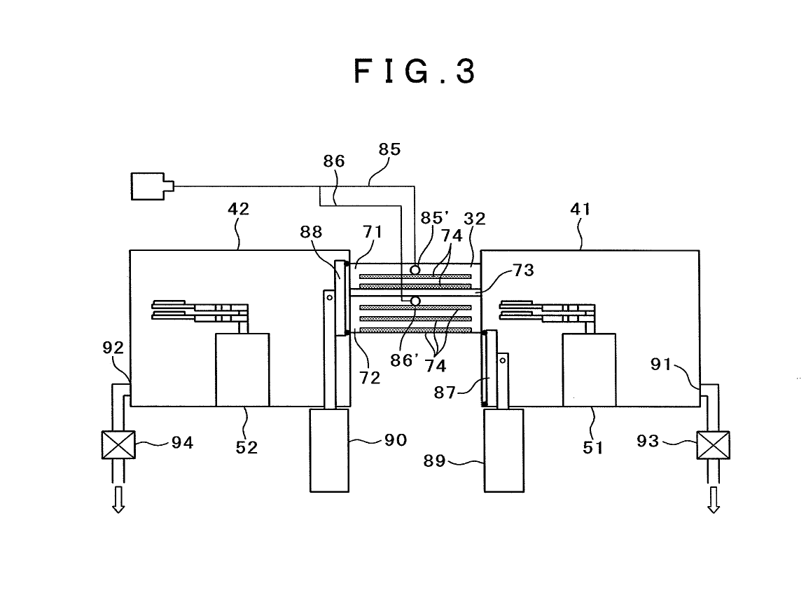

The vacuum transfer robots 51, 52 of the embodiment each include the first and second arms 81, 82 or 83, 84 which are each configured to permit each of the joint parts thereof to be independently and freely moved in the rotational direction or the height direction or to extend or contract the arm regardless of the movement of the other arm. Such a configuration permits the respective vacuum transfer robots 51 and 52 shown in FIG. 3 to access more than one delivery destination in parallel, enhancing the efficiency and performance of wafer transfer.

Next, the following description is made on operations of such a vacuum processing apparatus 100 processing the wafer.

A processing of a processing object wafer stored in a cassette placed on a cassette stand disposed on a front side of any one of the load ports 11, 12, 13 is started in response to a command from an unillustrated control unit which controls the operations of the vacuum processing apparatus 100 and is connected to the above-described vacuum processing apparatus 100 via unillustrated communication means, or a command from a control unit or the like of a production line where the vacuum processing apparatus is installed. Receiving the command from the control unit, the atmospheric transfer robot 22 takes a particular processing object wafer out of the cassette, transfers the taken-out processing object wafer to an unillustrated positioning apparatus coupled to the housing 21 and transfers this processing object wafer thus positioned by the positioning apparatus before processing into the lock chamber 31 coupled to a rear side of the housing 21. At this time, the lock chamber 31 is opened at its gate on the housing-21 side so that the interior thereof is adjusted to the atmospheric pressure or approximately to the atmospheric pressure.

Subsequently, the interior of the lock chamber 31 is hermetically closed by closing the gate and decompressed to a predetermined degree of vacuum. Then, the gate valve on the side of the first vacuum transfer chamber 41 is opened while the vacuum transfer robot 51 transfers the processing object wafer from the lock chamber into the first vacuum transfer chamber 41. In response to a command signal from the control unit, the vacuum transfer robot 51 transfers the processing object wafer to either the vacuum processing chamber 61 or the vacuum transfer intermediate chamber 32.

The processing object wafer transferred to the vacuum transfer intermediate chamber 32 is transferred by the vacuum transfer robot 52 in the second vacuum transfer chamber 42 to either of the vacuum processing chambers 62, 63 which is a destination processing chamber where the processing ordered by the control unit is performed. The processing object wafer transferred into the processing chamber in any one of the vacuum processing chambers 61 to 63 is subjected to the processing based on conditions previously set by the command signals from the control unit.

After completion of the processing, the processed wafer treated in the vacuum processing chamber 61 is transferred into the lock chamber 31 by the vacuum transfer robot 51. The processed wafer treated in the vacuum processing chamber 62 or 63 is taken out from the processing chamber by the second vacuum transfer chamber 42 and transferred to the lock chamber 31 via the vacuum transfer intermediate chamber 32.

The lock chamber 31 having received the processed wafer has the interior thereof hermetically closed by closing the gate valve thereof. In this state, the internal pressure of the lock chamber is increased to the atmospheric pressure or approximately to the atmospheric pressure. Subsequently, the gate valve of the lock chamber on the housing-21 side is opened. Then, the above-described atmospheric transfer robot 22 returns the wafer from the above-described lock chamber 31 to the original position in the cassette as a transfer origin.

The wafer transfer by the vacuum transfer robot 51 according to the embodiment is accomplished by sequentially performing exchange operations. With the unprocessed wafer carried on the hand of either the first arm 81 or the second arm 82, the robot drivably moves the other arm to a destination spot to which the unprocessed wafer is to be transferred, e.g., onto a sample stage in the vacuum processing chamber to perform the processing so as to place the processed wafer on the hand thereof and to carry out the processed wafer. Subsequently, the robot drivably moves the one arm to the destination spot so as to deliver the unprocessed wafer onto a sample mounting surface on the top of the sample stage. Particularly, form a state where the two arms are both contracted with the arm members folded down and are opposed to the destination spot, the robot sequentially performs the motion of extending the other arm by unfolding the arm members thereof toward the destination spot (e.g., onto the sample stage in the processing chamber) and placing the processed wafer on the hand thereof, followed by contracting the arm again to retract the arm from the destination spot and the motion of extending the folded one arm by unfolding the arm members thereof and further extending the arm toward the same destination spot as carrying the unprocessed wafer on the hand thereof, followed by contracting the arm again.

The time taken for wafer transfer is reduced by sequentially performing such exchange operations using the two arms at minimum motion intervals. Thus, the vacuum processing apparatus 100 is increased in processing efficiency. When the vacuum transfer robot 51 performs the above-described exchange operations to transfer the wafer to the lock chamber 31 or the vacuum transfer intermediate chamber 32, the robot may concurrently perform the motion of contracting and retracting the other arm carrying the wafer thereon from the destination spot (in this case, the lock chamber 31 or the stage or shelf retaining the wafer in the vacuum transfer intermediate chamber 32) and the motion of extending the one arm carrying the unprocessed wafer thereon to place above the destination spot.

According to the embodiment having such an arrangement, in a case where a dummy wafer is used to perform cleaning or seasoning before or after a processing object wafer is processed in any one of the vacuum processing chambers 61 to 63, the dummy wafer is transferred to the vacuum processing chamber scheduled to process the processing object wafer prior to or subsequent to the above-described processing object wafer. The dummy wafer is supplied from a cassette placed on any one of the above-described load ports 11, 12, 13 and storing the dummy wafer or from the dummy wafer store portion 14 disposed adjacent to the housing 21.

The dummy wafer is not used in one process of cleaning or seasoning. The range of use of dummy wafer is limited in terms of the number of uses or processing time which considers damage on or contamination of the wafer, and the dummy wafer can be used repetitively till the use thereof reaches the limited range.

The dummy wafer used for cleaning or seasoning in the above-described vacuum processing chamber is normally returned to the original cassette or the above-described dummy wafer store portion 14 so as not to interfere with the transfer of the processing object wafer. According to the embodiment, however, the dummy wafer is stored in the above-described vacuum transfer intermediate chamber 32 and allowed to standby in the vacuum transfer intermediate chamber 32 up to the time to use the dummy wafer.

In a case where a timing to use the dummy wafer in the vacuum processing chamber 61 comes, the dummy wafer allowed to standby in the above-described vacuum transfer intermediate chamber 32 is transferred to the above-described vacuum processing chamber 61 by the vacuum transfer robot 51 in the first vacuum transfer chamber 41 and is used for the processing of cleaning or seasoning. In a case where a timing to use the dummy wafer in the vacuum processing chamber 62 or 63 comes, the dummy wafer allowed to standby in the above-described vacuum transfer intermediate chamber 32 is transferred to the above-described vacuum processing chamber 62 or 63 by the vacuum transfer robot 52 in the second vacuum transfer chamber 42 and is used for the processing of cleaning or seasoning. Therefore, the influence of the transfer of the dummy wafer on the transfer of the processing object wafer can be minimized by repeating the above-described operations.

The vacuum transfer intermediate chamber 32 is a relay chamber between the first vacuum transfer chamber 41 and the second vacuum transfer chamber 42 and allows the dummy wafer to standby therein, which dummy wafer is to be required by the vacuum processing chamber 61 connected to the first vacuum transfer chamber 41. There is a case where the processing object wafer or dummy wafer is also used at the same time in the vacuum processing chamber 62 or 63 connected to the second vacuum transfer chamber 42. Accordingly, the vacuum transfer intermediate chamber 32 is provided with space to store such dummy wafers.

FIG. 3 is a vertical sectional view schematically showing structures of the vacuum transfer intermediate chamber 32 of the vacuum processing apparatus according to FIG. 1 and the first and second vacuum transfer chambers 41, 42 coupled to this vacuum transfer intermediate chamber. According to the embodiment as shown in the figure, the vacuum transfer intermediate chamber 32 includes two chambers vertically stacked on top of each other similarly to the lock chamber 31. More specifically, the vacuum transfer intermediate chamber 32 is provided with a removable partition plate 73 in a vacuum vessel defining an internal space to store wafers therein. The partitioning plate divides this space into upper and lower chambers, reducing migration of gas and particles between the two divided chambers.

The vacuum transfer intermediate chamber 32 is a station where wafers to be processed in the respective vacuum processing chambers 62, 63 or wafers processed in the respective vacuum processing chambers 62, 63 are stored. There may occur a state where with an unprocessed wafer to be processed in either of these vacuum processing chambers allowed to standby in the storage space in the vacuum transfer intermediate chamber 32, the wafer having been processed in the other vacuum processing chamber is transferred into the storage space of interest, or a state where with the processed wafer allowed to stand by in the storage space of interest for transfer to the lock chamber 31, an unprocessed wafer to be processed in either of the vacuum processing chamber 62, 63 is transferred into the space of interest. The above-described arrangement is effective to prevent that the unprocessed wafer and the processed wafer are present in the vacuum transfer intermediate chamber 32 at the same time and gas and products remaining around the latter wafer adversely affects the former wafer.

According to the embodiment, in particular, the two storage spaces in the vacuum transfer intermediate chamber 32, namely an upper storage section 71 and a lower storage section 72 are each configured to store two or more wafers vertically stacked with spacing defined on the respective upper sides and lower sides thereof. In each of the storage sections, the unprocessed wafer is stored at upper place while the processed wafer is stored at lower place. This is also effective to prevent the gas and particles remaining around the processed wafer from adversely affecting the unprocessed wafer in the individual storage spaces.

A wafer mounting part 74 (hereinafter, referred to as “wafer slot”) having a shelf structure for storing and retaining two or more wafers is disposed in each of the storage sections 71, 72. The mounting part 74 includes flanges which are arranged along two opposite side walls inside the vacuum transfer intermediate chamber 32 constituting the storage sections 71, 72 and extended therefrom toward the opposite side walls to define a sufficient length in horizontal direction (direction perpendicular to the drawing surface) for retaining the wafer on an outside circumference thereof and which are vertically arranged with predetermined spacing. Further, respective pairs of corresponding flanges on the side walls are disposed at the same heights. Thus the flanges constitute the shelf structure while opening a wide space at the wafer or the central portion of the storage section.

The number of slots of the mounting part 74 that constitute a plurality of steps is the number of wafers which can be temporarily stored in the mounting part 74 in the course of transfer between the vacuum processing chamber 62, 63 as the destination spot or the lock chamber 31 and the vacuum transfer intermediate chamber 32 during the operation of the vacuum processing apparatus 100. Namely, the number of steps of the mounting part 74, which is adapted to store and retain the dummy wafer therein, includes those for storing individual processing object wafers (unprocessed or processed) on a one-on-one basis and those for storing at least one dummy wafer.

According to the embodiment, in particular, the dummy wafer allowed to standby till it is used in any one of the vacuum processing chambers 61 to 63 is stored in the storage section 72 as the lower storage section. Accordingly, the mounting part 74 in the storage section 72 includes the slot having at least the number of steps corresponding to these wafers and dummy wafer.

In the slot of the mounting part 74, the step to store the processing object wafer and the step to store the dummy wafer are differentiated. The motion of the vacuum transfer robots 51, 52 is controlled by the control unit such that each of the processing object wafers and the dummy wafer is stored at a specified step. In this embodiment, the height positions of the steps not to store the dummy wafer are also specified for individual unprocessed ones and processed ones of the processing object wafers.

Of the steps in the slot of the mounting part 74 according to the embodiment which store the wafers while the vacuum processing apparatus is operated, a plurality of upper steps is defined as steps to retain the processing object wafers. In the mounting part 74 to store the dummy wafer, a lower one of the plural steps for the processing object wafers is used as the step to store the dummy wafer.

According to the embodiment as described above, when the vacuum transfer robot 51, 52 transfers the processing object wafer or the dummy wafer into or out of the mounting part 74 of the vacuum transfer intermediate chamber 32 which is a station as the transfer destination spot, exchange of the processed wafer and the unprocessed wafer is carried out by sequentially performing the motions of carrying in and carrying out the processed wafer and the unprocessed wafer. Hence, operation motions including the wafer transfer motion of the vacuum processing apparatus 100 are controlled by the control unit such that an event that an unprocessed processing object wafer and a processed processing object wafer are concurrently retained in the mounting part 74 does not occur during normal operation except for abnormality. On the other hand, the dummy wafer stored in the mounting part 74 is retained in the mounting part 74 during a time interval between times of cleaning or seasoning performed in any one of the vacuum processing chambers 61 to 63.

In a case where there is a need to process the processing object wafers in parallel in the vacuum processing chambers 61 to 63 and to perform the seasoning or cleaning in parallel in these processing chambers, three dummy wafers are required. Accordingly, the mounting part 74 in the storage section 72 includes as many slot steps as to store three dummy wafers at a maximum. The slot of the mounting part 74 of interest may have an optimum configuration according to the structure of the vacuum processing chamber of the vacuum processing apparatus 100 and use conditions of the dummy wafer.

For example, the first vacuum transfer chamber 41 is configured to be connectable with up to two vacuum processing chambers while the second vacuum transfer chamber 42 is configured to be connectable with up to three vacuum processing chambers. Therefore, in the case where the dummy wafers are used in parallel in the individual vacuum processing chambers, a storage space for five dummy wafers at maximum is required. Hence, the above-described storage section 72 may be provided with the mounting part 74 including a slot capable of storing five wafers at maximum.

Of the upper and lower storage sections 71, 72 of the vacuum transfer intermediate chamber 32 according to the embodiment, the upper storage section 71 stores only the unprocessed processing object wafers while the lower storage section 72 stores the processed processing object wafers and the dummy wafer. By separately storing the processed wafers and the unprocessed wafers in partitioned spaces in this manner, the migration of gas and product particles between these wafers is reduced. Particularly, contaminant transfer from the processed wafer to the unprocessed wafer is prevented. Similarly, the influence of the dummy wafer used at least more than once on the unprocessed wafer can be reduced by storing the dummy wafer to be used more than once in the lower chamber.

Of the plural slot steps disposed in the mounting part 74 of the lower storage section 72, the upper steps hold thereon the processed processing object wafers while the dummy wafers are placed on the steps thereunder. By adopting such a configuration, contamination sources such as particles and residual gas in the processing chamber are prevented from adversely affecting the processing object wafers. According to the embodiment, the slot of the mounting part 74 includes a plurality of steps to store the processing object wafers. Ina case where the slot further includes the step to store the dummy wafer under the above-described steps, the mounting part 74 of interest includes more than three steps.

Alternatively, both the storage sections 71, 72 each containing therein the mounting part 74 including a plurality of steps may be adapted to store the unprocessed and processed processing object wafers. As described above, the transfer by the vacuum transfer robots 51, 52 of the embodiment during normal operation is arranged such as to transfer the wafer into or out of the destination spot by exchanging the unprocessed wafer and the processed wafer, regardless of the type of wafers. In this case, the distance of vertical movement of the two arms of each vacuum transfer robot 51, 52 performing the above-described exchange operation is shorter when the arm transfers the unprocessed or processed wafer into one storage section.

When the unprocessed or processed processing object wafer is stored in one mounting part 74, the upper steps of the plural steps of the slot are used to store the unprocessed wafers while the lower steps under these upper steps are used to store the processed wafers. This arrangement also reduces the adverse effect of the processed wafer on the unprocessed wafer.

Further, when the dummy wafer is also stored in such a mounting part 74, the dummy wafer is stored in the mounting part 74 of the storage section 72. In this case, the mounting part 74 stores the dummy wafer in a step further lower than the steps to store the processed processing object wafers.

The processing object wafer processed in the vacuum processing chamber 62 or 63 connected to the second vacuum transfer chamber 42 is relayed to the processed wafer storage section 72 of the above-described vacuum transfer intermediate chamber 32. Even when the dummy wafer is stored in the slot step of the storage section 72, the processed processing object wafer and the dummy wafer stored in the above-described storage section may be exchanged by the above-described transfer mechanism of vacuum robot because the dummy wafer is to be used next in the above-described processing chamber 62 or 63.

In a case where the processed processing object wafer is placed on the first arm 83 of the vacuum transfer robot 52 in the second vacuum transfer chamber 42, for example, the robot may use the second arm 84 to take out the dummy wafer stored in the wafer slot in the above-described storage section 72 and may store the processed processing object wafer on the first arm 83 in the above-described wafer slot. Namely, the transfer of the processed wafer and the transfer of the dummy wafer can be sequentially performed so that the transfer of the dummy wafer does not interfere with the transfer of the processed wafer.

According to the embodiment, an opening for discharging the gas and particles in the vacuum transfer intermediate chamber 32 is not disposed at the vacuum transfer intermediate chamber 32. These gas and particles are discharged from an opening communicated with an exhaust unit such as a vacuum pump coupled to the first vacuum transfer chamber or the second vacuum transfer chamber 42 coupled to the vacuum transfer intermediate chamber 32. An inert gas is fed into the upper and lower storage sections 71, 72 of the vacuum transfer intermediate chamber 32 through side walls thereof. During the operation of the vacuum processing apparatus 100, the inert gas from a gas source is guided through inert gas supply lines 85, 86 and fed into the storage sections from openings 85′, 86′ thereof.

The vacuum transfer intermediate chamber 32 has gates at its ends in the in fore-aft direction (in the transverse direction as seen in the figure), each of which gates defines an opening which is divided by the partition plate 73 and through which the wafer is carried in or out. These gates are opened or hermetically closed by gate valves 87, 88 which are driven by drive mechanisms 89, 90, such as actuators, into movement in the vertical direction as seen in the figure, respectively. According to the embodiment, either one of the gate valves 87, 88 is moved upward to close the vacuum transfer intermediate chamber 32 while the vacuum processing apparatus 100 is operated and the wafer is transferred.

The openings 85′, 86′ are each located at the top of center of the side wall of each storage section 71, 72 in the fore-aft direction. The inert gas fed through these openings flows toward the opened gate and through the other gate along with the gas and particles in the individual storage sections 71, 72, entering either of the vacuum transfer chambers 41, 42 communicated therewith. Both of the vacuum transfer chambers 41, 42 are provided with exhaust ports 91, 92 at the bottom of inside walls and downward the gates so as to discharge the gas and particles from the chambers. The above-described inert gas and the other particles discharged from either of the exhaust ports 91, 92 are exhausted by either of the exhaust units such as vacuum pumps 93, 94 which are communicatably connected to the exhaust ports 91, 92 via pipe lines such as exhaust ducts as indicated by arrows in the figure. The gate valves 87, 88 maintain an open position or closed position till either of the valves operates in response to the occurrence of the wafer exchange operation by either of the vacuum transfer robots 51, 52.

When either of the vacuum transfer robots 51, 52 performs the wafer exchange operation to the vacuum transfer intermediate chamber 32, as holding the wafer on one of the two arms thereof, the control unit issues a command to a corresponding drive mechanism such as to open one of the gate valves 87, 88 that faces the corresponding one of the vacuum transfer robots. In a case where this one gate valve is already opened, the wafer exchange operation is performed by the one vacuum transfer robot.

In a case where it is determined that the one gate valve is closed, the control unit issues a command to the other drive mechanism such as to drive the other gate valve to close the gate corresponding to this gate valve. After detection of the closure of the other gate, the one gate valve is opened so that the wafer exchange is performed by the one vacuum transfer robot.

After the arm of the one vacuum transfer robot is retracted from the vacuum transfer intermediate chamber 32, the one gate valve keeps opening the one gate and the other gate valve keeps closing the other gate till the other vacuum transfer robot is required to perform the wafer exchange operation. According to the embodiment, with the vacuum processing apparatus 100 being in normal operation in which the wafer is transferred within the transfer unit including the vacuum transfer chambers 41, 42 and the vacuum transfer intermediate chamber 32, the vacuum transfer intermediate chamber 32 is maintained in a state to be closed by either one of the plural gate valves disposed at front and back sides thereof and to be opened by the other gate valve.

### Modified Example

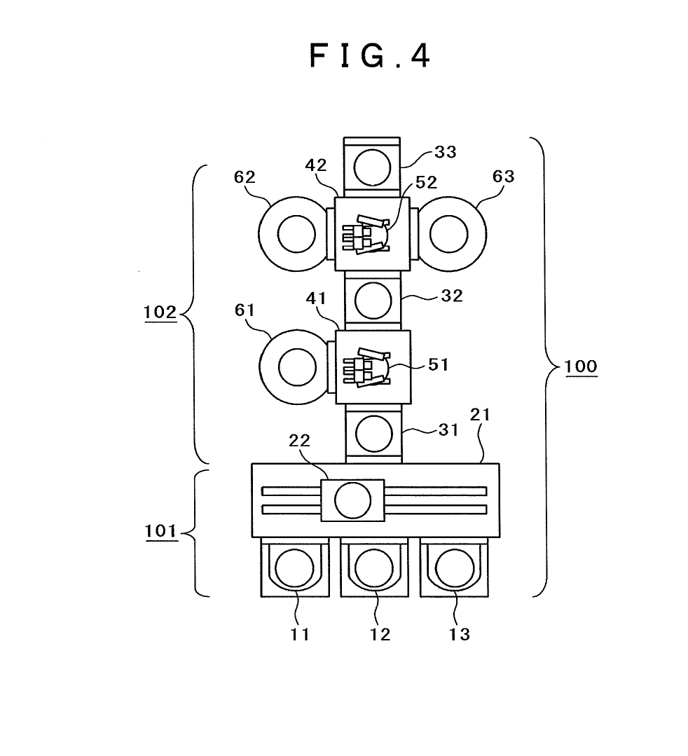

FIG. 4 schematically shows a general structure of a vacuum processing apparatus according to a modified example of the invention. As modified from the embodiment shown in FIG. 1, the example has a structure where a vacuum transfer intermediate chamber 33 having the same mechanism as the above-described vacuum transfer intermediate chamber 32 is coupled to the second vacuum transfer chamber 42 on the opposite side from the vacuum transfer intermediate chamber 32 attached to the second vacuum transfer chamber 42.

In the modified example having such a structure, the dummy wafer to be used in the vacuum processing chamber 61 connected to the above-described first vacuum transfer chamber 41 is stored in the vacuum transfer intermediate chamber 32 interposed between the first vacuum transfer chamber 41 and the second vacuum transfer chamber 42 and coupled to these, while the dummy wafer to be used in the vacuum processing chamber 62 and 63 connected to the above-described second vacuum transfer chamber 42 is stored in the vacuum transfer intermediate chamber 33 attached to the second vacuum transfer chamber 42.

The vacuum transfer intermediate chamber 33 has a gate which is an opening communicating with the second vacuum transfer chamber 42 and opened or hermetically closed by an unillustrated gate valve. According to the modified example, the second vacuum transfer chamber 42 has four vacuum vessels disposed therearound and coupled thereto and is provided with four gate valves for opening and closing communication with these vacuum vessels. Each of these gate valves is opened with the other gate valves closed and maintained in the closed state. Namely, every one of the four gate valves is exclusively opened so that a vacuum vessel is communicated with the second vacuum vessel 42 via a gate corresponding to the opened gate valve while the other vacuum vessels are prevented from communicated with these vessels. Thus, the expansion of contamination is reduced.

The vacuum transfer intermediate chamber 33 has the same structure as the vacuum transfer intermediate chamber 32 in that the vacuum transfer intermediate chamber 33 has an internal space to store the wafers divided into upper and lower sections by an unillustrated partition plate so as to reduce migration of the particles between these space sections. In these storage sections as internal wafer storage spaces, the dummy wafers to be used only in the respective vacuum processing chambers 62, 63 are stored and retained in the respective shelf-like slots each having the plural steps vertically arranged with spacing. The dummy wafer is used more than once for cleaning process or seasoning process of the corresponding vacuum processing chamber 62, 63.

In such processes, the dummy wafer is taken out and transferred to the corresponding vacuum processing chamber 62, 63 as the destination spot by the vacuum, transfer robot 52 and is transferred to the original position after the cleaning process or the seasoning process. In contrast to the case where the dummy wafer is stored in the vacuum transfer intermediate chamber 32, the vacuum transfer robot 52 does not exchange the dummy wafer in the vacuum transfer intermediate chamber 33. A gate valve disposed on the front side of the vacuum transfer intermediate chamber 33 is closed when any one of the other three gate valves corresponding to the gates facing into the first vacuum transfer chamber 41 is opened. After detection of the closure of this opened valve, this gate valve is opened and maintained in the open state during a period which also includes time of operation of taking out the dummy wafer and then, is closed just before the operation of opening the other gate.

In the vacuum transfer intermediate chamber 33 as well, openings for supplying the inert gas are formed at the top of center of inside walls of the upper and lower storage sections in the fore-aft direction. With the gate valve on the front side of the vacuum transfer intermediate chamber 33 opened, the inert gas is introduced into the individual storage sections and flows through the gate and into the second vacuum transfer chamber 42 along with the residual gas and particles in the individual storage sections. The inert gas is exhausted through the exhaust port 92 at the bottom of the side wall of the second vacuum transfer chamber 42 and discharged to the outside by the vacuum pump 94.

According to the above-described embodiments, the storage space such as the structure of the wafer slot in the vacuum transfer intermediate chamber required for storing the dummy wafer can be minimized.

The above-described embodiments are adapted to prevent the decrease in transfer efficiency of the processing object wafer as a result of the transfer of processing object wafer alternating with the transfer of dummy wafer. Further, a specialized mechanism, space and the like for the use of dummy wafer but not for the purpose of processing the processing object wafer are not required and hence, the increase in the apparatus cost attributable to such specialized mechanism and the like can be reduced.

### REFERENCE SIGNS LIST

11 to 13 . . . LOAD PORT
21 . . . HOUSING
22 . . . ATMOSPHERIC TRANSFER ROBOT
31 . . . LOCK CHAMBER
32,33 . . . VACUUM TRANSFER INTERMEDIATE CHAMBER
41 . . . FIRST VACUUM TRANSFER CHAMBER
42 . . . SECOND VACUUM TRANSFER CHAMBER
51,52 . . . VACUUM TRANSFER ROBOT
61,62,63 . . . VACUUM PROCESSING CHAMBER
71,72 . . . STORAGE SECTION
73 . . . PARTITION PLATE
74 . . . MOUNTING PART
81,83 . . . FIRST ARM
82,84 . . . SECOND ARM
101 . . . ATMOSPHERE-SIDE BLOCK
102 . . . VACUUM-SIDE BLOCK

1. A vacuum processing apparatus comprising:
an atmospheric transfer chamber which is provided with a cassette stand at the front thereof and in which a processing object wafer is transferred in the atmospheric pressure; a plurality of vacuum transfer chambers each of which is disposed rearward of the atmospheric transfer chamber and has a rectangular shape in plan, in which the processing object wafer is transferred under reduced pressure and which is coupled with a vacuum processing chamber on the periphery thereof, the vacuum processing chamber in which the processing object wafer is transferred and positioned under reduced pressure and is processed using plasma generated therein; an intermediate chamber which is disposed between the plural vacuum transfer chambers and interconnects these and in which the processing object wafer is placed and stored in the course of transfer between the vacuum transfer chambers; and a lock chamber which is disposed between the vacuum transfer chamber and a back side of the atmospheric transfer chamber and interconnects these, wherein the processing object wafer stored in a cassette placed on the cassette stand is transferred to any one of the plural vacuum processing chambers via the lock chamber and subjected to processing,
wherein a storage section for dummy wafer is disposed in the intermediate chamber, the dummy wafer placed in one of the processing chambers when a processing is performed on the dummy wafer by using the plasma generated in the processing chamber of interest and under a condition different from that of the above processing.

2. The vacuum processing apparatus according to claim 1, wherein the plural vacuum transfer chambers are arranged in a fore-aft direction with the intermediate chamber interposed therebetween, and the dummy wafer is stored in a lower part of the wafer storage space in the intermediate chamber.

3. The vacuum processing apparatus according to claim 1, wherein the storage space in the intermediate chamber includes a storage space for unprocessed wafer and a storage space for processed wafer, and the dummy wafer is stored in the storage space for processed wafer.

4. The vacuum processing apparatus according to claim 1, further comprising a partition plate disposed in the intermediate chamber and partitioning the interior thereof into two storage spaces, wherein the two storage spaces include a portion to store both of the unprocessed wafer and the processed wafer and a portion to store the dummy wafer is disposed in at least one of these two storage spaces and under the portion to store the processed wafer.

5. The vacuum processing apparatus according to claim 1, wherein the plural vacuum transfer chambers include first and second vacuum transfer chambers coupled together with the intermediate chamber interposed therebetween, and a dummy wafer to be used in a vacuum processing chamber coupled to the first vacuum transfer chamber is stored in the intermediate chamber while a dummy wafer to be used in a processing chamber connected to the second vacuum transfer chamber is stored in another dummy wafer storage chamber coupled to the second vacuum transfer chamber.

6. The vacuum processing apparatus according to claim 2, wherein the storage space in the intermediate chamber includes a storage space for unprocessed wafer and a storage space for processed wafer, and the dummy wafer is stored in the storage space for processed wafer.

7. The vacuum processing apparatus according to claim 2, further comprising a partition plate disposed in the intermediate chamber and partitioning the interior thereof into two storage spaces, wherein the two storage spaces include a portion to store both of the unprocessed wafer and the processed wafer and a portion to store the dummy wafer is disposed in at least one of these two storage spaces and under the portion to store the processed wafer.

8. The vacuum processing apparatus according to claim 2, wherein the plural vacuum transfer chambers include first and second vacuum transfer chambers coupled together with the intermediate chamber interposed therebetween, and a dummy wafer to be used in a vacuum processing chamber coupled to the first vacuum transfer chamber is stored in the intermediate chamber while a dummy wafer to be used in a processing chamber connected to the second vacuum transfer chamber is stored in another dummy wafer storage chamber coupled to the second vacuum transfer chamber.
